(19) United States
(12) Patent Application Publication
(10) Pub. No.: US 2017/0141878 A1
(43) Pub. Date: May 18, 2017

(54) SYSTEMS AND METHODS FOR SENDING DATA FROM NON-VOLATILE SOLID STATE DEVICES BEFORE ERROR CORRECTION

(71) Applicant: Western Digital Technologies, Inc., Irvine, CA (US)

(72) Inventors: Dejan VUCINIC, San Jose, CA (US); Robert MATEESCU, San Jose, CA (US); Minghai QIN, San Jose, CA (US); Zvonimir Z. BANDIC, San Jose, CA (US)

(21) Appl. No.: 14/942,516

(22) Filed: Nov. 16, 2015

(51) Int. Cl. H04L 1/00; H03M 13/15

(52) U.S. Cl. CPC H04L 1/0057; H03M 13/152

(57) ABSTRACT

Methods and systems for performing operations in a communications protocol are provided. A memory controller can retrieve data packets from the memory and send each retrieved data packet to a host, as each data packet is retrieved. The memory controller can retrieve an error correcting code (ECC) packet corresponding to the retrieved data packets and execute an ECC algorithm to identify and correct potential errors in the retrieved plurality of data packets. The memory controller can send any corrected data packets to the host if any of the retrieved data packets had errors and send a completion packet to the host.

### FIELD OF THE DISCLOSURE

The present disclosure relates to systems and methods for sending data stored in non-volatile solid state devices and particularly sending data before completion of error correction.

### RELATED DISCLOSURE

Non-volatile solid state devices (SSDs) are widely used for primary and secondary storage in computer systems. Some non-volatile memories, such as Phase Change Memory (PCM), Resistive RAM (ReRAM), and Magnetic RAM (MRAM), have bit error rates that can be higher than bit error rates in Dynamic Read Access Memories (DRAMs), but can be much lower than bit error rates in NAND flash memories. Therefore, these intermediate bit error rates require better error correction than the short Hamming codes used in DRAMs. This can result in long latencies when running the error correction algorithm. For example, implementing an error correcting code (ECC), such as a full BCH code (from the acronym of the code inventors, Raj Bose, D. K. Ray-Chaudhuri, and Alexis Hocquenghem), e.g., on a 512 B block, can take about half as much time as reading the bits from the storage medium.

Moreover, the probability of error in any block, e.g., a 4 kB, can be low enough such that most blocks will have no error. Accordingly, on most reads the latency due to the error correction algorithm is wasted. In addition, conventional systems implement a non-pipelined flow, which normally read from the storage medium all the bits for reconstructing a single 512 B block, then they run the ECC algorithm, and can start sending the data to the host after the ECC algorithm has completed. Therefore, transmitting the block is delayed until the ECC algorithm completes.

### SUMMARY

The present disclosure relates to methods and systems for performing operations according to a communications protocol.

One embodiment can include a method for performing operations in a communications protocol. The method can include the steps of providing a target in communication with a host and a memory and receiving, by the target, a first command from the host comprising a request for a plurality of data packets from the memory. The method can also include the steps of retrieving, by the target, the plurality of data packets from the memory and sending, by the target, each retrieved data packet to the host, as each data packet is retrieved. The method can further include the steps of retrieving, by the target, an error correcting code (ECC) packet corresponding to the retrieved plurality of data packets and executing, by the target, an ECC algorithm to identify and correct potential errors in the retrieved plurality of data packets. The method can also include the steps of sending, by the target, corrected data packets to the host if any of the retrieved data packets had errors and sending, by the target, a completion packet to the host.

One alternative embodiment can include a method for performing operations in a communications protocol. The method can include the steps of providing a target in communication with a host and a memory and receiving, by the target, a first command from the host comprising a request for a plurality of data packets from the memory. The method can also include the steps of retrieving, by the target, the plurality of data packets from the memory and sending, by the target, each retrieved data packet to the host, as each data packet is retrieved, except the last retrieved data packet. The method can also include the steps of retrieving, by the target, an error correcting code (ECC) packet corresponding to the retrieved plurality of data packets and executing, by the target, an ECC algorithm to identify and correct potential errors in the retrieved plurality of data packets. The method can further include the steps of sending, by the target, corrected data packets to the host if any of the retrieved data packets had errors and sending, by the target, the last retrieved data packet.

One alternative embodiment can include a memory controller for performing operations in a communications protocol. The memory controller can comprise an interface controller in communication with a host and a memory configured to receive a first command from the host comprising a request for a plurality of data packets from the memory and a storage controller. The storage controller can be configured to retrieve the plurality of data packets from the memory and instruct the interface controller to send each retrieved data packet to the host, as each data packet is retrieved, except the last retrieved data packet. The storage controller can be further configured to retrieve an error correcting code (ECC) packet corresponding to the retrieved plurality of data packets and execute an ECC algorithm to identify and correct potential errors in the retrieved plurality of data packets. The storage controller can be further configured to instruct the interface controller to send corrected data packets to the host if any of the retrieved data packets had errors and instruct the interface controller to send the last retrieved data packet.

One alternative embodiment can include a memory controller for performing operations in a communications protocol. The memory controller can comprise an interface controller in communication with a host and a memory configured to receive a first command from the host comprising a request for a plurality of data packets from the memory and a storage controller. The storage controller can be configured to retrieve the plurality of data packets from the memory and perform an error detection algorithm, on each retrieved data packet to identify whether the retrieved data packet contains an error. The storage controller can be further configured to instruct the interface controller to send each retrieved data packet to the host, as each data packet is retrieved, except the last retrieved data packet and retrieve an error correcting code packet corresponding to the retrieved plurality of data packets and execute an ECC algorithm to identify and correct potential errors in the retrieved plurality of data packets. The storage controller can be further configured to instruct the interface controller to send corrected data packets to the host if any of the retrieved data packets had errors and instruct the interface controller to send the last retrieved data packet.

### BRIEF DESCRIPTION OF THE DRAWINGS

Various objects, features, and advantages of the present disclosure can be more fully appreciated with reference to the following detailed description when considered in connection with the following drawings, in which like reference numerals identify like elements. The following drawings are for the purpose of illustration only and are not intended to be limiting of the invention, the scope of which is set forth in the claims that follow.

FIG. 1 illustrates an exemplary system implementing a communication protocol, in accordance with embodiments of the present disclosure.

FIG. 2A illustrates an exemplary conventional implementation for sending data from a storage medium.

FIGS. 2B-2C illustrate exemplary implementations for sending data from a storage medium, according to aspects of the disclosure.

FIG. 3A illustrates an exemplary conventional implementation for sending data from a storage medium.

FIGS. 3B-3C illustrate exemplary implementations for sending data from a storage medium, according to aspects of the disclosure.

FIG. 4 illustrates an exemplary method for sending data from a storage medium, according to aspects of the disclosure.

FIG. 5 illustrates an exemplary method for sending data from a storage medium, according to aspects of the disclosure.

### DETAILED DESCRIPTION

Systems and methods for sending data stored in non-volatile memories are provided. Data packets can be sent to a host once they are retrieved from the non-volatile memory before performing error correction. Once all the data packets of a block have been retrieved from the non-volatile memory, error correction can be performed. If any data packet was retrieved with errors, it can be corrected and re-sent to the host.

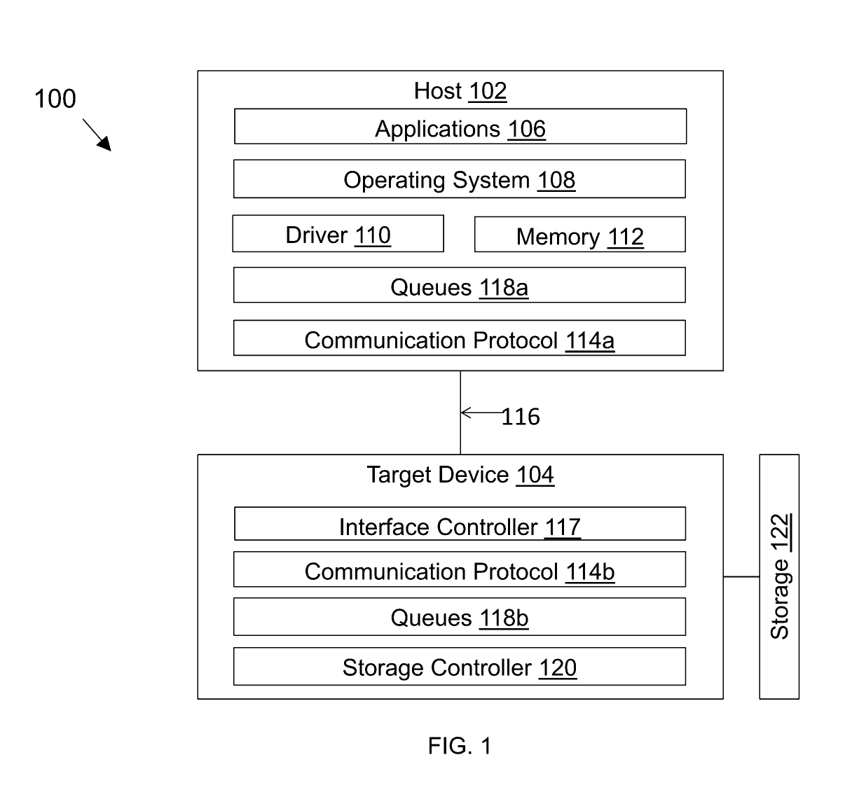

FIG. 1 illustrates an exemplary system 100 implementing a communication protocol, in accordance with embodiments of the present disclosure. System 100 includes host 102 in communication with target device 104 and storage 122. Host 102 includes user applications 106, operating system 108, driver 110, host memory 112, queues 118a, and communication protocol 114a. Target device 104 includes interface controller 117, communication protocol 114b, queues 118b, and storage controller 120 in communication with storage 122.

Host 102 can run user-level applications 106 on operating system 108. Operating system 108 can run driver 110 that interfaces with host memory 112. In some embodiments, memory 112 can be a DRAM. Host memory 112 can use queues 118a to store commands from host 102 for target 104 to process. Examples of stored or enqueued commands can include read or write operations from host 102. Communication protocol 114a can allow host 102 to communicate with target device 104 using interface controller 117.

Target device 104 can communicate with host 102 using interface controller 117 and communication protocol 114b. Communication protocol 114b can provide queues 118 to access storage 122 via storage controller 120. For example, user-level applications 106 can generate storage memory 122 access requests for data. Target device 104 can implement error correction codes to correct errors when memory blocks are retrieved from storage 122.

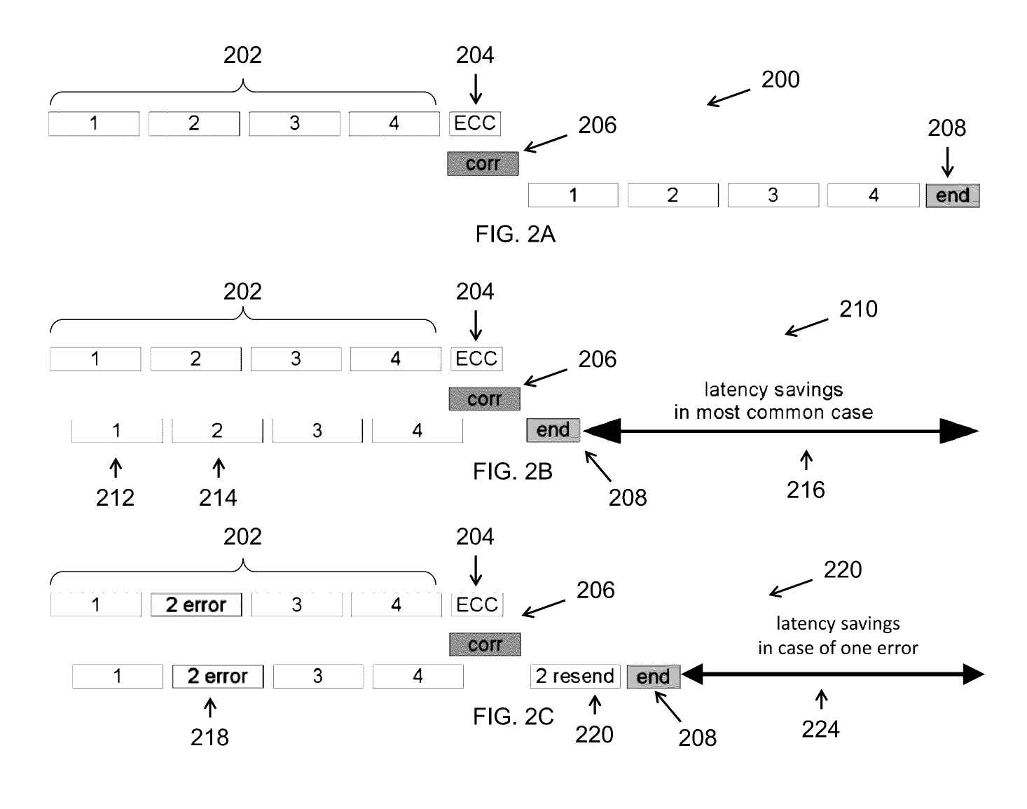

As discussed above, running an error correction code, such as a full BCH code, for example on a 512 B block, can consume about half as much time as reading the data from storage 122. Conventional systems, e.g., systems that implement a non-pipelined flow, normally read from the storage medium all the bits for reconstructing one block, then they can run the ECC algorithm, and can start sending the corrected data to the host after the ECC algorithm has completed. This is illustrated in FIG. 2A, generally at 200, which illustrates an exemplary way to transmit packets, e.g., four packets 202, from a storage medium to a host. In the particular example, the system first reads packets 202 and the ECC packet 204, then performs the error correction algorithm 206 to determine whether any packet has errors and to correct any detected errors. Then the system can send the four blocks to the host and the completion packet 208 to signal that the transfer has completed. A person of ordinary skill would understand the ECC bits can be multiple packets depending on how those bits are arranged on the medium by design of the correction scheme.

According to aspects of the disclosure, the data packets from the storage medium are transmitted to the host before the error correction algorithm is implemented. This is illustrated in FIG. 2B, generally at 210. The disclosed systems and methods first retrieved packets 202. As each packet is retrieved from the storage medium, it is transmitted to the host. For example, when the first packet is retrieved, it is transmitted to the host 212. When the second packet is retrieved, it is also transmitted to the host 214. This continues until all the packets 202 are retrieved from the storage medium. After all packets are retrieved, the ECC packet 204 is read to implement the error correction algorithm 206. If the algorithm does not detect any errors, the end packet 208 is transmitted to signal the host that the transfer has completed. As shown in FIG. 2B, the disclosed method can result in significant latency savings 216 in the most common case when there are no errors in the data packets retrieved from the storage device. For example, the latency savings can be approximately the time required to transmit all data packets to the host.

The disclosed systems and methods can result in latency savings, even in the case where the retrieved data from the storage medium contain errors. FIG. 2C generally at 220 illustrates the latency savings when transmitting data packets to the host in the case of errors in the retrieved data packets. Specifically, in the illustrated example, the second data packet 218 contains an error. Because the disclosed method does not wait for the error detection and correction algorithm to complete before the packet is transmitted to the host, the packet 218 will be received at the host with the error. When the error is detected 206, the erroneous data packet 218 is corrected, and the correct data packet 220 is retransmitted to the host. If more than one packets were retrieved from the storage medium with errors, then all erroneous packets are corrected and resent to the host. The end packet 208 is then transmitted to signal the host that the transfer has completed. As shown also in FIG. 2C, the disclosed method can result in significant latency savings even when there are errors in the data packets retrieved from the storage device, for example, when there is one error in the retrieved data 224.

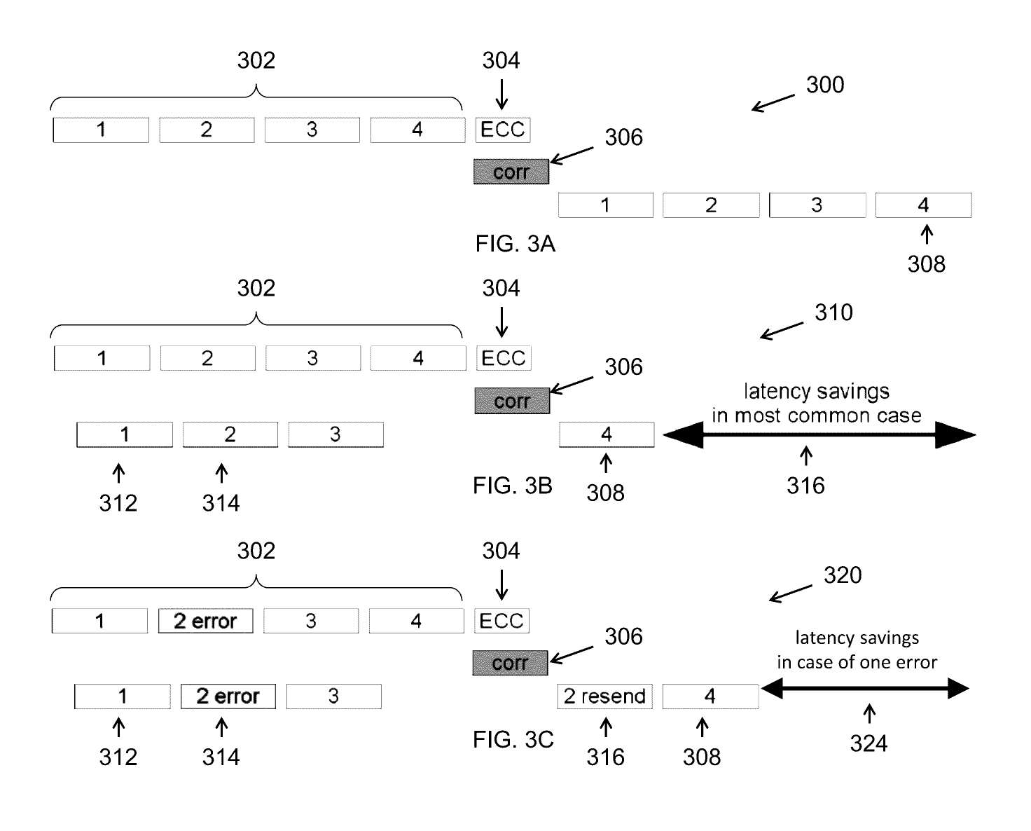

FIG. 3A illustrates an alternative implementation of a non-pipelined flow of a conventional system. Specifically, FIG. 3A, generally at 300, illustrates another exemplary way to transmit packets, e.g., four packets 302, from a storage medium to a host, without sending a separate completion packet. In the particular example, the system first retrieved packets 302 and the ECC packet 304, then performs the error correction algorithm 306, to determine whether any packet has errors and to correct any detected errors. Then the system can send the four blocks to the host. The last packet 308 can also act as the completion packet that can signal to the host that the transfer has completed. Exemplary protocols that can eliminate completion signals in favor, for example, of other completion detection procedures are described in U.S. patent application Ser. No. 14/466,538, entitled “Ack-less protocol for noticing completion of read requests,” filed on Aug. 22, 2014 and U.S. patent application Ser. No. 14/489,881, entitled “Acknowledgement-less protocol for solid state drive interface,” filed on Sep. 18, 2014, the contents of both are incorporated herein in their entirety.

According to alternative aspects of the disclosure, the data packets 302 from the storage medium can be transmitted to the host before the error correction algorithm is implemented, without a transmission of a completion packet. This is illustrated in FIG. 3B, generally at 310. The disclosed system and methods first retrieve packets 302. As each packet is retrieved from the storage medium, it is transmitted to the host. For example, when the first packet is retrieved 312, it is transmitted to the host. When the second packet is retrieved 314, it is also transmitted to the host. According to aspects of the disclosure, the last packet 308 is not transmitted to the host, until the error detection and correction algorithm is implemented. Specifically, after the ECC packet 304 is retrieved from the storage medium, the ECC algorithm is implemented 306. If there are no errors detected, the last packet 308 is transmitted to the host. When the last packet 308 is received at the host, it can signal to the host that the transfer has completed. As shown in FIG. 3B, the disclosed method can result in significant latency savings 316 in the most common case when there are no errors in the data packets retrieved from the storage device.

FIG. 3C generally at 220 illustrates the latency savings when transmitting data packets to the host in the case of errors in the data packets and when there is no completion packet. Specifically, in the illustrated example, the second data packet 314 contains an error. Because the disclosed method does not wait for the error detection and correction algorithm to complete before the packet is transmitted to the host, the second packet 314 will be received at the host with the error. According to aspects of the disclosure, the last packet 308 is not transmitted until the error detection and correction algorithm is implemented. When the error in the second packet 314 is detected 306, the erroneous data packet 314 is corrected, and the correct data packet 316 is retransmitted to the host. After the corrected packet 316 is sent, the method can send the last data packet 308. When the last packet 308 is received at the host, it can signal to the host that the transfer has completed. A person of ordinary skill would understand that if the last data packet is retrieved with errors, a corrected data packet will be sent to the host. As shown in FIG. 3C, the disclosed method can result in significant latency savings even when there are errors in the data packets retrieved from the storage device, for example, when there is one error in the retrieved data 324.

According to alternative aspects of the disclosure, after an error is detected, only a subset of the erroneously retrieved packet is re-transmitted to the host, e.g., only the subset that contained the errors. When the subset is received at the host, it can overwrite the appropriate portion of the packet.

According to alternative aspects of the disclosure, when a data packet is retrieved from the storage medium, an error detection algorithm is performed, e.g., a syndrome check (calculation of the polynomial that returns a value indicating how many bits are in error), to identify whether any errors in the retrieved data packet. If none of the retrieved packets have any errors, then no further ECC algorithm is implemented.

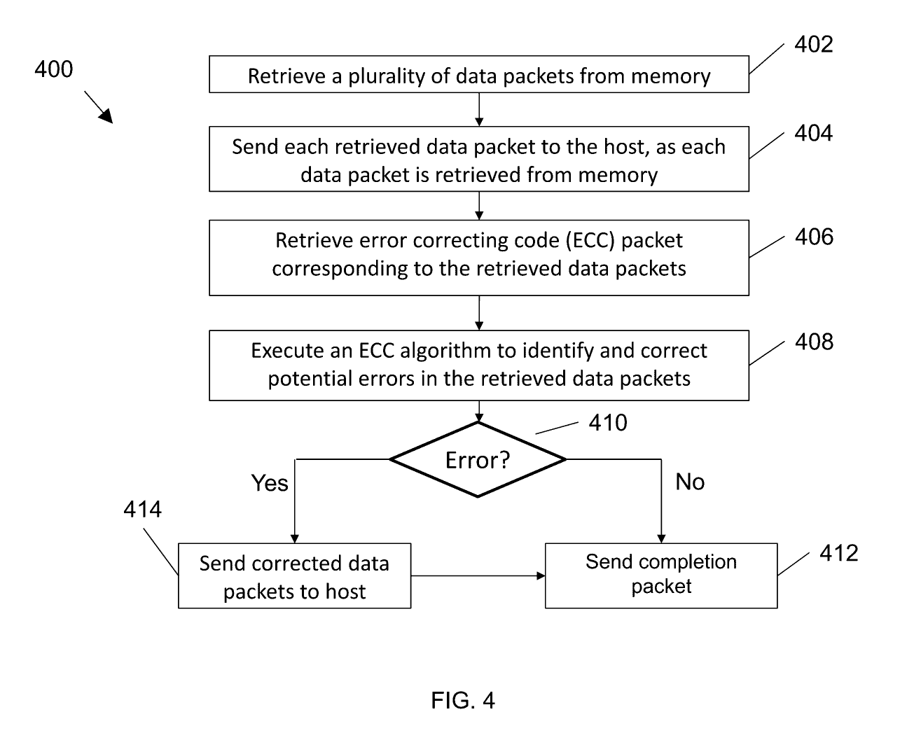

FIG. 4 illustrates a flow diagram 400 of an exemplary method for sending data packets to a host, according to aspects of the disclosure. A memory controller can retrieve a plurality of data packets from memory 402. When the memory controller retrieves a data packet, it sends it to the host 404. The memory controller can also retrieve an ECC packet corresponding to the retrieved data packets 406. Once the ECC packet is retrieved, the memory controller can execute an ECC algorithm to identify and correct potential errors in the retrieved data packets 408. The method then can check whether there is an error in the retrieved data packets 410. If there are not detected errors, the memory controller can send a completion packet to the host 412. If there are errors in the retrieved data, the memory controller can send the corrected data packets 414, and then the completion packet 412 to the host.

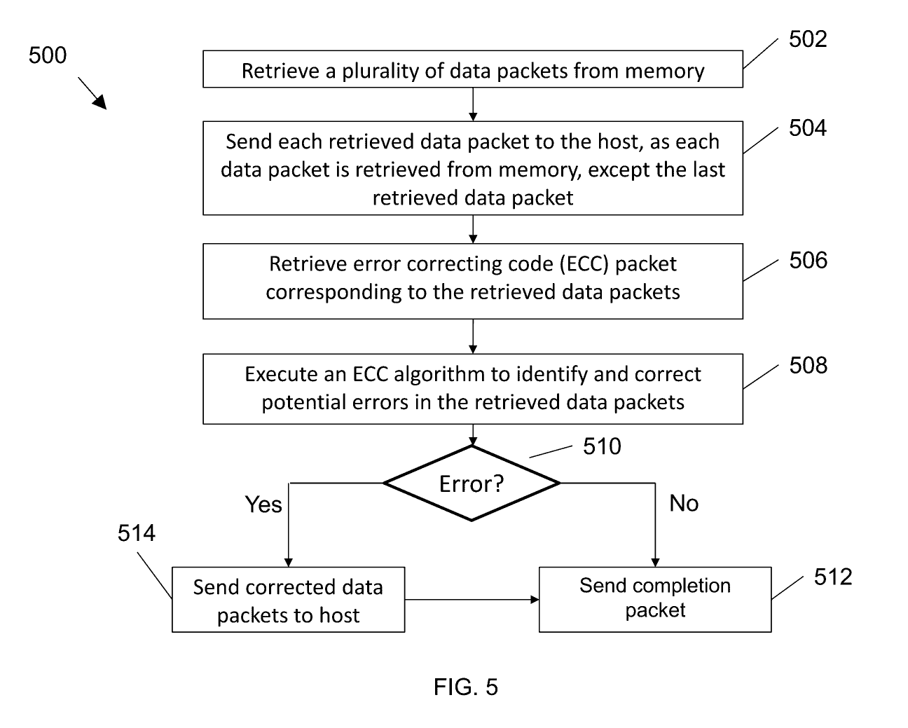

FIG. 5 illustrates a flow diagram 500 of an exemplary method for sending data packets to a host, according to alternative aspects of the disclosure. A memory controller can retrieve a plurality of data packets from memory 502. When the memory controller retrieves a data packet, it can send each packet to the host 504, except for the last retrieved data packet. The memory controller can also retrieve an ECC packet corresponding to the retrieved data packets 506. Once the ECC packet is retrieved, the memory controller can execute an ECC algorithm to identify and correct potential errors in the retrieved data packets 508. The method then can check whether there is an error in the retrieved data packets 510. If there are not detected errors, the memory controller can send the last retrieved packet to the host 512. If there are errors in the retrieved data, the memory controller can send the corrected data packets 514, and then the last retrieved packet 512 to the host.

Those of skill in the art would appreciate that the various illustrations in the specification and drawings described herein can be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware, software, or a combination depends upon the particular application and design constraints imposed on the overall system. Skilled artisans can implement the described functionality in varying ways for each particular application. Various components and blocks can be arranged differently (for example, arranged in a different order, or partitioned in a different way) all without departing from the scope of the subject technology.

Furthermore, an implementation of the communication protocol can be realized in a centralized fashion in one computer system, or in a distributed fashion where different elements are spread across several interconnected computer systems. Any kind of computer system, or other apparatus adapted for carrying out the methods described herein, is suited to perform the functions described herein.

A typical combination of hardware and software could be a general purpose computer system with a computer program that, when being loaded and executed, controls the computer system such that it carries out the methods described herein. The methods for the communications protocol can also be embedded in a computer program product, which comprises all the features enabling the implementation of the methods described herein, and which, when loaded in a computer system is able to carry out these methods.

Computer program or application in the present context means any expression, in any language, code or notation, of a set of instructions intended to cause a system having an information processing capability to perform a particular function either directly or after either or both of the following a) conversion to another language, code or notation; b) reproduction in a different material form. Significantly, this communications protocol can be embodied in other specific forms without departing from the spirit or essential attributes thereof, and accordingly, reference should be had to the following claims, rather than to the foregoing specification, as indicating the scope of the invention.

The communications protocol has been described in detail with specific reference to these illustrated embodiments. It will be apparent, however, that various modifications and changes can be made within the spirit and scope of the disclosure as described in the foregoing specification, and such modifications and changes are to be considered equivalents and part of this disclosure.

1. A method for performing operations in a communications protocol, the method comprising:
providing a target in communication with a host and a memory;
receiving, by the target, a first command from the host comprising a request for a plurality of data packets from the memory;
retrieving, by the target, the plurality of data packets from the memory;
sending, by the target, each retrieved data packet to the host, as each data packet is retrieved;
retrieving, by the target, an error correcting code (ECC) packet corresponding to the retrieved plurality of data packets;
executing, by the target, an ECC algorithm to identify and correct potential errors in the retrieved plurality of data packets;
sending, by the target, corrected data packets to the host if any of the retrieved data packets had errors; and
sending, by the target, a completion packet to the host.

2. The method of claim 1, wherein the memory is a non-volatile memory.

3. The method of claim 2, wherein the non-volatile memory is phase change memory (PCM).

4. The method of claim 1, wherein the ECC algorithm implements a BCH code.

5. A method for performing operations in a communications protocol, the method comprising:
providing a target in communication with a host and a memory;
receiving, by the target, a first command from the host comprising a request for a plurality of data packets from the memory;
retrieving, by the target, the plurality of data packets from the memory;
sending, by the target, each retrieved data packet to the host, as each data packet is retrieved, except the last retrieved data packet;
retrieving, by the target, an error correcting code (ECC) packet corresponding to the retrieved plurality of data packets;
executing, by the target, an ECC algorithm to identify and correct potential errors in the retrieved plurality of data packets;
sending, by the target, corrected data packets to the host if any of the retrieved data packets had errors; and
sending, by the target, the last retrieved data packet.

6. The method of claim 5, wherein the memory is a non-volatile memory.

7. The method of claim 6, wherein the non-volatile memory is phase change memory (PCM).

8. The method of claim 5, wherein the ECC algorithm implements a BCH code.

9. A method for performing operations in a communications protocol, the method comprising:
providing a target in communication with a host and a memory;
receiving, by the target, a first command from the host comprising a request for a plurality of data packets from the memory;
retrieving, by the target, the plurality of data packets from the memory;
performing an error detection algorithm, on each retrieved data packet to identify whether the retrieved data packet contains an error;
sending, by the target, each retrieved data packet to the host, as each data packet is retrieved;
retrieving, by the target, an error correcting code (ECC) packet corresponding to the retrieved plurality of data packets;
executing, by the target, an ECC algorithm to correct potential errors in the retrieved plurality of data packets, if any of the retrieved data packets had errors;
sending, by the target, corrected data packets to the host if any of the retrieved data packets had errors; and
sending, by the target, a completion packet to the host.

10. The method of claim 9, wherein the memory is a non-volatile memory.

11. A memory controller comprising:
an interface controller in communication with a host and a memory configured to receive a first command from the host comprising a request for a plurality of data packets from the memory; and
a storage controller configured to:
retrieve the plurality of data packets from the memory;
instruct the interface controller to send each retrieved data packet to the host, as each data packet is retrieved;
retrieve an error correcting code (ECC) packet corresponding to the retrieved plurality of data packets;
execute an ECC algorithm to identify and correct potential errors in the retrieved plurality of data packets;
instruct the interface controller to send corrected data packets to the host if any of the retrieved data packets had errors; and
instruct the interface controller to send a completion packet to the host.

12. The memory controller of claim 11, wherein the memory is a non-volatile memory.

13. The memory controller of claim 12, wherein the non-volatile memory is phase change memory (PCM).

14. The memory controller of claim 11, wherein the ECC algorithm implements a BCH code.

15. A memory controller comprising:
an interface controller in communication with a host and a memory configured to receive a first command from the host comprising a request for a plurality of data packets from the memory; and
a storage controller configured to:
retrieve the plurality of data packets from the memory;
instruct the interface controller to send each retrieved data packet to the host, as each data packet is retrieved, except the last retrieved data packet;
retrieve an error correcting code (ECC) packet corresponding to the retrieved plurality of data packets;
execute an ECC algorithm to identify and correct potential errors in the retrieved plurality of data packets;
instruct the interface controller to send corrected data packets to the host if any of the retrieved data packets had errors; and
instruct the interface controller to send the last retrieved data packet.

16. The memory controller of claim 15, wherein the memory is a non-volatile memory.

17. The memory controller of claim 16, wherein the non-volatile memory is phase change memory (PCM).

18. The memory controller of claim 15, wherein the ECC algorithm implements a BCH code.

19. A memory controller comprising:
an interface controller in communication with a host and a memory configured to receive a first command from the host comprising a request for a plurality of data packets from the memory; and
a storage controller configured to:
retrieve the plurality of data packets from the memory;
perform an error detection algorithm, on each retrieved data packet to identify whether the retrieved data packet contains an error;
instruct the interface controller to send each retrieved data packet to the host, as each data packet is retrieved, except the last retrieved data packet;
retrieve an error correcting code (ECC) packet corresponding to the retrieved plurality of data packets;
execute an ECC algorithm to identify and correct potential errors in the retrieved plurality of data packets;
instruct the interface controller to send corrected data packets to the host if any of the retrieved data packets had errors; and
instruct the interface controller to send the last retrieved data packet.

20. The method of claim 19, wherein the memory is a non-volatile memory.
